(19) United States
(12) Patent Application Publication
(10) Pub. No.: US 2026/0150372 A1
(43) Pub. Date: May 28, 2026

(54) SEMICONDUCTOR STRUCTURE

(71) Applicant: TAIWAN SEMICONDUCTOR MANUFACTURING COMPANY LTD., HSINCHU (TW)

(72) Inventors: KAU-CHU LIN, TAICHUNG CITY (TW); CHAN-YU HUNG, TAINAN CITY (TW); FEI-YUN CHEN, HSINCHU (TW); CHING-HSIUNG HSU, HSINCHU COUNTY (TW)

(21) Appl. No.: 18/961,513

(22) Filed: Nov. 27, 2024

(51) Int. Cl. H01L 29/417; H01L 29/06; H01L 29/45; H01L 29/66; H01L 29/78

(52) U.S. Cl. CPC H10D 64/257; H10D 30/0281; H10D 30/603; H10D 30/65; H10D 62/107; H10D 62/116; H10D 62/127; H10D 64/62; H10D 84/0149; H10D 84/835; H10D 84/836; H10D 84/834

(57) ABSTRACT

A semiconductor structure includes a gate structure, an isolation structure, a source region, a drain region, a source contact structure, and a drain contact structure. The gate structure is disposed over a substrate and extends in a first direction. The isolation structure is disposed between the gate structure and the substrate. The source region and the drain region are disposed at two sides of the isolation structure, and extend in the first direction. The source contact structure is coupled to the source region, and the drain contact structure is coupled to the drain region. Each of the source contact structure and the drain contact structure has a strip configuration and extends in the first direction.

### BACKGROUND

The electronics industry is experienced an ever-increasing demand for smaller and faster electronic devices that are able to support greater numbers of increasingly complex and sophisticated functions. Accordingly, there is a continuing need in the semiconductor industry for improvements in low-cost, high-performance, low-power integrated circuits (ICs). Thus far, such goals have been achieved in large part by scaling down semiconductor IC dimensions (e.g., minimum feature size) and thereby improving production efficiency and reducing associated costs. However, such downscaling has also introduced increased complexity to the semiconductor manufacturing process. Thus, the realization of continued advances in semiconductor ICs and devices requires corresponding advances in semiconductor manufacturing processes and technology.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a layout structure illustrating a high voltage (HV) transistor device in accordance with aspects of the present disclosure in one or more embodiments.

FIG. 2 is a cross-sectional view of an HV transistor device in accordance with aspects of the present disclosure in one or more embodiments.

FIGS. 3 to 5 are cross-sectional views of a multiple-Vt semiconductor structure in various stages of a method for forming a semiconductor structure in accordance with aspects of the present disclosure in one or more embodiments.

FIG. 6 is a flowchart of a method for forming a semiconductor structure in accordance with aspects of the present disclosure in one or more embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

With ongoing down-scaling of integrated circuits, power supply voltages of the circuits may be reduced. However, an amount of the voltage reduction may be different in different circuits or regions. For example, threshold voltage (Vt) requirements of memory circuits may be different from those of core circuits. In some embodiments, transistors that provide low voltage functionality may have operating voltages less than approximately 1.8V in CMOS technology. In addition, transistors that provide medium voltage functionality may have operating voltages of approximately 8V, while transistors that provide high voltage functionality may have operating voltages of approximately 25V. A multiple-Vt capability is therefore desired for device design.

However, integration of a multiple-Vt device in a FinFET device can raise some issues. In some comparative approaches, contact structures formed by middle-end-of-line (MEOL) processes may be formed to couple to the low-voltage (LV), medium-voltage (MV) and high-voltage (HV) devices, respectively. Contact structures that are formed by same operations have same dimensions. To sustain HV applications, quantities of the contact structures used in the HV devices are increased, thereby requiring a greater area (e.g., an area for accommodating a drain region of the HV device) for accommodating such group of contact structures. Such requirement of greater area presents a challenge to the scaling down of semiconductor IC dimensions.

Embodiments of a semiconductor structure are therefore provided. The semiconductor structure is formed in an HKMG process in accordance with the embodiments. The semiconductor structure includes a non-planar device and a planar device. For example but not limited thereto, a planar device for an HV application may be integrated with a non-planar device such as a FinFET device for an LV application. In some embodiments, the semiconductor structure includes contact structures for both HV devices and LV devices. The contact structures for the HV devices are made in a slot configuration or a strip configuration, which is sustainable to the HV application. Further, the strip-type contact structure may replace a group of small island contact structures. Accordingly, the strip-type contact structure is able to reduce an area required for accommodating a source/drain region of the HV devices. Further, a process window for forming the contact structures is improved due to the relatively larger strip-type contact structures.

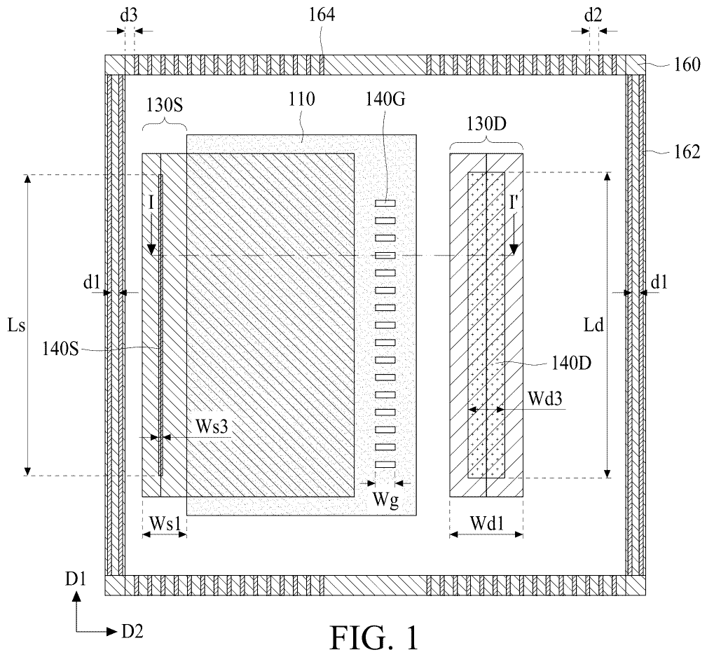

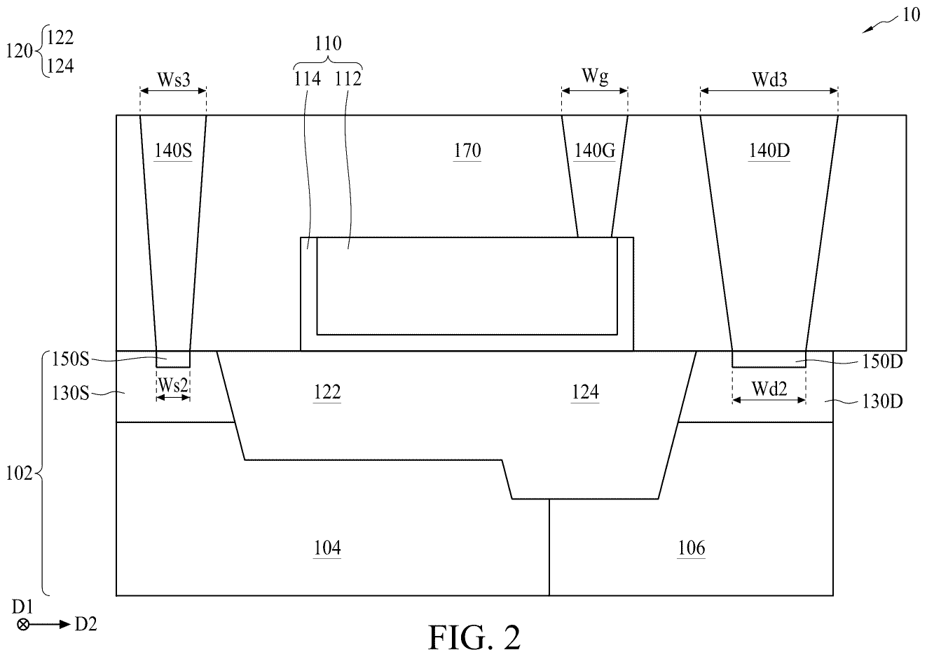

Please refer to FIGS. 1 and 2, wherein FIG. 1 is a layout structure illustrating an HV transistor device in accordance with aspects of the present disclosure in one or more embodiments, and FIG. 2 is a cross-sectional view of an HV transistor device in accordance with aspects of the present disclosure in one or more embodiments. In some embodiments, FIG. 2 is a cross-sectional view taken along line I-I′ of FIG. 1. In some embodiments, a HV transistor device 10 is provided. The HV transistor device 10 can be an n-type high-voltage transistor device, but the disclosure is not limited thereto. For example, in some alternative embodiments, the HV transistor device 10 can be a p-type HV transistor device. In some embodiments, the HV transistor device 10 can be referred to as a high-voltage laterally-diffused MOS (HV LDMOS) transistor device, a high-voltage extended-drain MOS (HV EDMOS) transistor device, or any other HV device.

In some embodiments, the HV transistor device 10 includes a substrate 102. The substrate 102 can include an elementary semiconductor material including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate may include a SiGe alloy with a gradient Ge feature in which a Si/Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy. Furthermore, the substrate 102 may be a semiconductor on insulator, such as silicon on insulator (SOI). In some embodiments, the substrate 102 may include a doped epitaxial layer or a buried layer. In some embodiments, the substrate 102 may have a multilayer structure, or may include a multilayer compound semiconductor structure.

In some embodiments, the HV transistor device 10 includes a well region 104, as shown in FIG. 2. In other embodiments, other well regions or doped regions may be disposed between a bottom of the well region 104 and the substrate 102. The well region 104 includes dopants of a first conductivity type. In some embodiments, the first conductivity type is a p-type. In some embodiments, p-type dopants include boron (B), other group III elements, or a combination thereof. In some embodiments, the well region 104 can be referred to as a high-voltage p-type well (HVPW).

In some embodiments, the HV transistor device 100 includes another well region 106. In other embodiments, other well regions or doped regions may be disposed between a bottom of the well region 106 and the substrate 102. The well region 106 includes dopants of a second conductivity type. The first conductivity type and the second conductivity type are complementary to each other. In some embodiments, when the first conductivity type is a p-type, the second conductivity type is an n-type. In some embodiments, n-type dopants include arsenic (As), phosphorus (P), other group V elements, or any combination thereof. In some embodiments, the well region 106 can be referred to as a high-voltage n-type well (HVNW). In some embodiments, the well region 106 may be referred to as a drift region. In some embodiments, the well region 106 may be in contact with the well region 104, but the disclosure is not limited thereto.

The HV transistor device 100 includes a gate structure 110 disposed over the substrate 102. As shown in FIG. 2, the gate structure 110 overlaps a portion of the well region 104 and a portion of the well region 106. In some embodiments, the gate structure 110 includes a gate conductive layer 112. In some embodiments, the gate conductive layer 112 includes a work function metal layer that provides a metal gate with an n-type work function or a p-type work function. Materials having the p-type work function include ruthenium, palladium, platinum, cobalt, nickel, conductive metal oxide, and other suitable materials. Materials having the n-type work function include hafnium, zirconium, titanium, tantalum, aluminum, metal carbides (e.g., hafnium carbide, zirconium carbide, titanium carbide, and aluminum carbide), aluminides, or other suitable materials.

In some embodiments, when the gate structure 110 is formed by an HKMG process, such as a replacement poly-gate (RPG) process, the gate structure 110 may include a high-k dielectric layer 114. In some embodiments, the high-k gate dielectric layer 114 can be a single layer or a multi-layer structure. In some embodiments, the high-k dielectric layer 114 is a multi-layer structure that includes an interfacial layer and a high-k dielectric layer. The interfacial layer can include dielectric material such as silicon oxide, silicon nitride, silicon oxynitride, other dielectric material, or a combination thereof. The high-k dielectric layer can include high-k dielectric material such as HfO₂, HfSiO, HfSiON, HfTaO, HfTiO, HfZrO, other suitable high-k dielectric materials, or a combination thereof. In some embodiments, the high-k dielectric material can further be selected from metal oxides, metal nitrides, metal silicates, transition metal-oxides, transition metal-nitrides, transition metal-silicates, metal oxynitrides, metal aluminates, and combinations thereof.

In some embodiments, the gate structure 110 may include spacers disposed over sidewalls. However, the spacers are omitted from FIGS. 1 and 2. In some embodiments, the spacers include multiple layers, but the disclosure is not limited thereto. In some embodiments, the spacers are made of silicon nitride (SiN), silicon carbide (SiC), silicon oxide (SiO_{X}), silicon oxynitride (SiON), silicon carbide, or another suitable material, but the disclosure is not limited thereto.

In some embodiments, the HV transistor device 100 includes an isolation structure 120 disposed between the substrate 102 and the gate structure 110, thereby separating the gate structure 110 from the substrate 102 (i.e., the well region 104 and the well region 106). In some embodiments, the isolation structure 120 includes a first portion 122 and a second portion 124 coupled to the first portion 122. In some embodiments, the first portion 122 and the second portion 124 may include a multilayered structure. In some alternative embodiments, the first portion 122 and the second portion 124 may be a single-layered structure. In some embodiments, the first portion 122 and the second portion 124 may include same materials. In such embodiments, the first portion 122 and the second portion 124 may include same materials formed by different forming techniques. In some embodiments, the first portion 122 and the second portion 124 may include different materials. In some embodiments, a thickness of the first portion and a thickness of the second portion 124 are different. For example, the thickness of the first portion 122 is less than the thickness of the second portion 124. In such embodiments, the thickness of the first portion 122 may be approximately half the thickness of the second portion 124, but the disclosure is not limited thereto.

The HV transistor device 100 further includes a source region 130S and a drain region 130D disposed at two sides of the gate structure 110, and at two sides of the isolation structure 120. In some embodiments, a bottom of the source region 130S is in contact with the well region 104, and a bottom of the drain region 130D is in contact with the well region 106, as shown in FIG. 2. However, in other embodiments, other doped regions may be added between the source region 130S and the well region 104, and/or added between the drain region 130D and the well region 106, depending on product design. Each of the source region 130S and the drain region 130D includes the second conductivity type, and doping concentrations of the source region 130S are similar to doping concentration of the drain region 130D. In some embodiments, a width Ws1 of the source region 130S is less than a width Wd1 of the drain region 130D. In some embodiments, the first portion 122 of the isolation structure 120, which is thinner than the second portion 124, is near the source region 1230S, while the second portion 124 of the isolation structure 120, which is thicker than the first portion 122, is near the drain region 130D, as shown in FIG. 2.

In some embodiments, the HV transistor device 100 includes a source contact structure 140S coupled to the source region 130S, and a drain contact structure 140D coupled to the drain region 130D. In some embodiments, the HV transistor device 100 further includes a silicide structure 150S disposed between the source region 130S and the source contact structure 140S, and a silicide structure 150D disposed between the drain region 130D and the drain contact structure 140D. In some embodiments, the silicide structures 150S and 150D may be formed using a self-aligned silicidation (salicide) process, but the disclosure is not limited thereto. In some embodiments, the silicide structures 150S and 150D may include NiSix, for example. The silicide structures 150S and 150D may alternatively comprise other silicide materials.

In some embodiments, the source contact structure 140S and the drain contact structure 140D include same materials. In some embodiments, the source contact structure 140S and the drain contact structure 140D may be formed by a damascene process. For example, in some embodiments, a dielectric structure 170 is formed over the substrate 102, the dielectric structure 170 is patterned to form trenches (not shown) exposing a portion of the source region 130S and a portion of the drain region 130D, and the trenches are filled with a conductive material. In some embodiments, the silicide structure 150S is formed over the portion of the source region 130S exposed through the trench, and the silicide structure 150D is formed over the portion of the drain region 130D exposed through the trench. In such embodiments, the silicide structures 150S and 150D are formed prior to the depositing of the conductive material. In some embodiments, a width Ws2 of the silicide structure 150S is less than a width Wd2 of the silicide structure 150S.

In some embodiments, the HV transistor device 100 includes a gate contact structure 140G disposed in the dielectric structure 170 and coupled to the gate structure 110. In some embodiments, the gate contact structure 140G may be formed prior to the forming of the source contact structure 140S and the drain contact structure 140D. In some alternative embodiments, the gate contact structure 140G is formed after the forming of the source contact structure 140S and the drain contact structure 140D.

Referring to FIGS. 1 and 2, in some embodiments, the gate structure 110, the source region 130S and the drain region 130D of the HV transistor device 100 all extend in a direction D1. Further, each of the source contact structure 140S and the drain contact structure 140D includes a strip configuration and extends in the direction D1, as shown in FIG. 1. In such embodiments, the silicide structures 150S and 150D may also have a strip configuration. Further, in such embodiments, each of the source contact structure 140S and the drain contact structure 140D has a pair of short sides and a pair of long sides. In some embodiments, a width Ws3 of the source contact structure 140S is defined as a lateral distance between the pair of long sides of the source contact structure 140S and measured in the direction D2, and a width Wd3 of the drain contact structure 140D is defined as a lateral distance between the pair of long sides of the drain contact structure 140D and measured in the direction D2. Further, the width Ws3 of the source contact structure 140S is less than a width Wd3 of the drain contact structure 140D.

In some embodiments, a length Ls of the source contact structure 140S is defined as a lateral distance between the pair of short sides of the source contact structure 140S and measured in the direction D1, and a length Ld of the drain contact structure 140D is defined as a lateral distance between the pair of short sides of the drain contact structure 140D and measured in the direction D1. In some embodiments, the length Ls of the source contact structure 140S is greater than the width Ws3 of the source contact structure 140S, and the length Ld of the drain contact structure 140D is greater than the width Wd3 of the drain contact structure 140D. Further, the length Ls of the source contact structure 140S is equal to the length Ld of the drain contact structure 140D.

In some embodiments, the gate contact structure 140G may also include a strip configuration and extend in the direction D2. The gate contact structure 140G therefore has a pair of long sides and a pair of short sides, and a width Wg of the gate contact structure 140G is defined as a distance between the two short sides and measured in the direction D2. In some embodiments, the width Wg of the gate contact structure 140G is less than the width Wd3 of the drain contact structure 140D. In some embodiments, the width Wg of the gate contact structure 140G is equal to or greater than the width Ws3 of the source contact structure 140S.

Additionally, in some embodiments, the HV transistor device 100 includes at least a guard ring 160 surrounding the gate structure 110, the source region 130S, the drain region 130D and the isolation structure 120, as shown in FIG. 1. In some embodiments, the transistor device 100 further includes a plurality of contact structures 162 disposed in a first pair of sides of the guard ring 160, and a plurality of contact structures 164 disposed in a second pair of sides of the guard ring 160. The contact structures 162 and 164 all extend in the direction D1. In some embodiments, distance d1 between adjacent contact structures 162 are equal to each other, and distances d2 between adjacent contact structures 164 are equal to each other. In some embodiments, the distances d1 between adjacent contact structures 162 are equal to the distances d2 between adjacent contact structures 164. In some embodiments, a distance d3 between a contact structure 162 and its adjacent contact structure 164 is equal to each of the abovementioned distances d1 and d2. In some embodiments, a length of the contact structure 162 is greater than a length of the contact structure 164. In some embodiments, a width of the contact structure 162 is equal to a width of the contact structure 164. In some embodiments, the width of the contact structure 162 and the width of the contact structure 164 are equal to the width Ws3 of the source contact structure 140S, but the disclosure is not limited thereto.

In some embodiments, the HV transistor device 100 includes one strip-type drain contact structure 140D in the drain region 130D, and one strip-type source contact structure 140S in the source region 130S. In some comparative embodiments, a plurality of islet-type drain contact structures may be adopted. In such comparative embodiments, a width and a length of the islet-type drain contact structure may each be 0.0013 micrometers. In such comparative embodiments, the width and the length of each islet-type contact structures are much less than the width Wd3 and the Ld of the strip-type drain contact structure 140D. For example but not limited thereto, the length Ld of the strip-type drain contact structure 140D may be over 10,000 times the length of the islet-type drain contact structure, while the width Wd3 of the strip-type drain contact structure 140D may be over 100 times the length of the islet-type drain contact structure. To sustain the HV application, a quantity of the tiny islet-type drain contact structures is increased to over 1,000. Further, space is needed between adjacent islet-type drain contact structures. To accommodate so many islet-type drain structures, an area of the comparative drain region is increased. In contrast to the comparative approach, in the embodiments of the present disclosure, an area of the drain region 130D required for accommodating the one strip-type drain contact structure 140D is reduced. For example but not limited thereto, an area for accommodating the strip-type drain region 130D may be one-sixth of the area for accommodating the plural tiny islet-type drain contact structures. Accordingly, benefit is achieved by scaling down the HV transistor device 100. Further, the formation of one strip-type drain structure 140D over the drain region 130D and one strip-type source structure 140S over the source region 130S improve the process window.

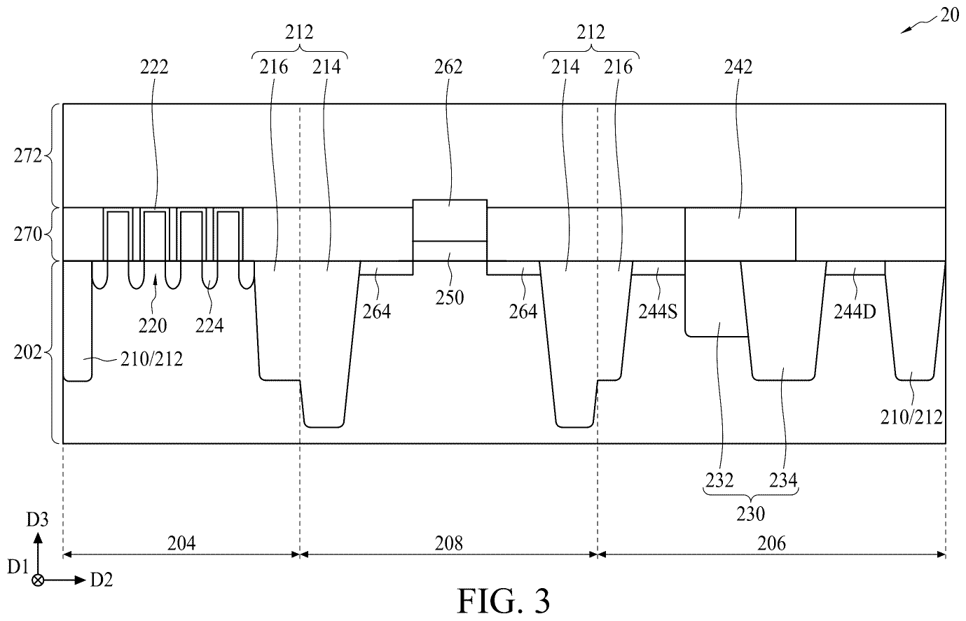

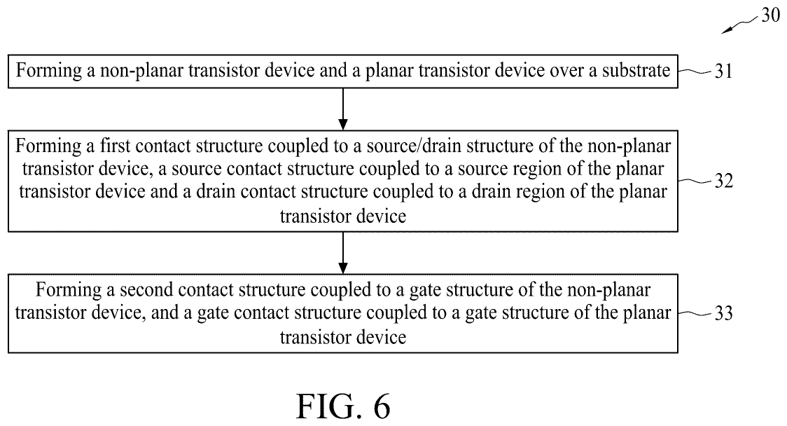

In some embodiments, the HV transistor device 100 is integrated in non-planar device approaches. For example, the HV transistor device 100 may be integrated in Fin-like field-effect transistor (FinFET) approaches. In some embodiments, the HV transistor device 100 is integrated in multiple-Vt semiconductor structure approaches. The description below refers to FIGS. 3 to 6, wherein FIGS. 3 to 5 are schematic drawings of a semiconductor structure in various stages in a method for forming a semiconductor structure 30, and FIG. 6 is a flowchart of a method forming the semiconductor structure.

Referring to FIG. 6, in some embodiments, in operation 31, a non-planar transistor device and a planar transistor device are formed over a substrate. Please refer to FIG. 3, which is a schematic drawing illustrating an intermediate semiconductor structure 20 including the non-planar transistor device and the planar transistor device formed in a substrate 202. In some embodiments, the substrate 202 may have a region 204 and a region 206, but the disclosure is not limited thereto. For example, in some embodiments, the substrate 202 may have another region 208. The arrangement of the regions 204, 206 and 208 may be modified depending on product design.

In some embodiments, the substrate 202 may be a semiconductor substrate such as a silicon substrate. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. The substrate 202 may include various layers, including conductive or insulating layers formed on a semiconductor substrate. The substrate 202 may include various doping configurations depending on design requirements, as is known in the art. For example, different doping profiles (e.g., n wells or p wells) may be formed on the substrate 202 in regions designed for different device types (e.g., n-type field-effect transistors (NFET), or p-type field-effect transistors (PFET)). A suitable doping may include ion implantation of dopants and/or diffusion processes.

The regions 204, 206 and 208 are defined for accommodating different devices. For example, the region 204 may accommodate a low-voltage (LV) device while the region 206 may accommodate a high-voltage (HV) device. In some embodiments, the HV device referred herein is a device having an operating voltage greater than that of the LV device. For example, but not limited thereto, the HV device may have an operating voltage between approximately 25V and approximately 35V, while the LV device may have an operating voltage between approximately 0.8V and approximately 1.8V. However, operating voltages can vary for different applications, and thus are not limited herein. For example, the LV device may have an operating voltage lower than approximately 2V. In some embodiments, the region 208 may accommodate a middle-voltage (MV) device. The MV device referred to herein is a device having an operating voltage between those of the LV device and the HV device. For example but not limited thereto, the MV device may have an operating voltage of approximately 8V.

In some embodiments, the HV device and MV device may be planar FET devices, while the LV device may be a non-planar FET device, such as a FinFET device.

In some embodiments, the semiconductor structure 20 includes isolation structures 210 and 212 disposed in the substrate 202 between the regions 204, 206 and 208. Further, the isolation structures 210 and 212 electrically isolate devices to be formed in the regions 204, 206 and 208. For example, the isolation structure 212 electrically isolates devices disposed in the region 204 from devices disposed in the region 208, and electrically isolates devices disposed in the region 206 from the devices disposed in the region 208. In some embodiments, the isolation structure 210 or 212 separates the devices disposed in the region 204 from devices in other regions (not shown), and separates the devices disposed in the region 206 from devices in other regions (not shown).

In some embodiments, the isolation structures 210 and 212 may include same dielectric materials and may have same configurations. In some embodiments, the isolation structures 210 and 212 may include various dielectric materials and various configurations. For example, in some embodiments, the isolation structure 212 may include two portions 214 and 216 coupled to each other. In some embodiments, a thickness of the portion 214 is greater than a thickness of the portion 216. The thickness of the portion 214 and the thickness of the portion 216 may be adjusted according to various product design. Additionally, a width of the portion 214 and a width of the portion 216 may be adjusted according to product design.

In some embodiments, a top surface of the substrate 202, top surfaces of the isolation structures 212 and top surfaces of the isolation structures 210 may be aligned (i.e., coplanar) with each other, as shown in FIG. 3.

In some embodiments, the regions 204, 206 and 208 may include well regions disposed therein, though not shown. For example, well regions may be formed in the substrate 202 in the region 206 and 208. In such embodiments, a concentration of dopants in the well region in the region 206 is different from a concentration of dopants in the well region in the region 208, in order to accommodate devices of different operating voltages. In some embodiments, a high-voltage p-type well (HVPW) 104 and a high-voltage n-type well (HVNW) 106 (similar to those shown in FIG. 2) may be formed in the region 206 for an HV application, though not shown in FIG. 3.

In some embodiments, at least a fin structure 220 and at least a gate structure 222 are disposed in the region 204. In some embodiments, the gate structure 222 is a metal gate structure. As shown in FIG. 3, the metal gate structure 222 extends in a direction D1, and the fin structure 220 extends in a direction D2 different from the direction D1. In some embodiments, the direction D1 and the direction D2 are perpendicular to each other. Further, the fin structure 220 protrudes from the substrate 202 in a direction D3 perpendicular to the directions D1 and D2. In some embodiments, a top surface of the fin structure 220 may be aligned with the top surface of the substrate 202, the top surface of the isolation structure 210 and the top surfaces of the isolation structures 212.

In some embodiments, portions of the fin structure 220 covered by the metal gate structure 222 serve as a channel region, and portions of the fin structure 220 exposed through the metal gate structure 222 serve as a source/drain structure 224. In some embodiments, a height of the source/drain structure 224 may be greater than heights of the fin structure 220. In some embodiments, the source/drain structure 224 may be formed by forming recesses in the fin structure 220 and growing a strained material in the recesses by an epitaxial (epi) process. In addition, a lattice constant of the strained material may be different from a lattice constant of the fin structure 220. Accordingly, the source/drain structure 224 may serve as a stressor that improves carrier mobility. In some embodiments, top surfaces of the source/drain structures 224 may be coplanar with or higher than the top surface of the fin structure 220. In some embodiments, the fin structure 220, the metal gate structure 222 and the source/drain structures 224 form a non-planar device, such as a FinFET device. In some embodiments, the FinFET device may include other elements depending on product design. For example, the FinFET device may include sidewall spacers over sidewalls of the metal gate structure 222. However, such elements are omitted for brevity.

In some embodiments, an isolation structure 230 may be disposed in the region 206. A top surface of the isolation structure 230 is aligned with the top surface of the fin structure 220. The isolation structure 230 is similar to the isolation structure 120 shown in FIG. 2. For example, the isolation structure 230 includes a first portion 232 and a second portion 234 coupled to the first portion 232. The first portion 232 is similar to the first portion 122 of the isolation structure 120, and the second portion 234 is similar to the second portion 124 of the isolation structure 120. Therefore, details of the first portion 232 and the second portion 234 of the isolation structure 230 are omitted for brevity.

In some embodiments, a gate structure, such as a metal gate structure 242, is disposed over the isolation structure 230. In such embodiments, the isolation structure 230 is disposed between the substrate 202 and the metal gate structure 242. In some embodiments, a source region 244S and a drain region 244D are disposed in the substrate 202 in the region 206. The metal gate structure 242, the source region 244S, and the drain region 244D may form a planar FET device. In some embodiments, the planar FET device may include other elements depending on product design. For example, the planar FET device may include sidewall spacers over sidewalls of the metal gate structure 242. However, such elements are omitted for brevity.

In some embodiments, the planar FET device in the region 206 is an HV device, such as the HV transistor device 100. In such embodiments, the metal gate structure 242, the source region 244S and the drain region 244D extend in the direction D1. Further, a width of the drain region 244D is greater than a width of the source region 244S. In some embodiments, the configuration and arrangement of the metal gate structure 242, the source region 244S and the drain region 244D may be similar to those of the gate structure 110, the source region 130S and the drain region 130D of the HV transistor device 100; therefore, repeated description is omitted for brevity.

In some embodiments, a gate dielectric layer 250 is disposed over the substrate 202 in the region 208, and a gate structure such as a metal gate structure 262 is disposed over the gate dielectric layer 250. In such embodiments, the gate dielectric layer 250 is disposed between the substrate 202 and the metal gate structure 262. In some embodiments, source/drain regions 264 are disposed in the substrate 202 at two sides of the metal gate structure 262 in the region 208. The gate dielectric layer 250, the metal gate structure 262, and the source/drain region 264 may form a planar FET device. In some embodiments, the planar FET device may include other elements depending on product design. For example, the planar FET device may include sidewall spacers over sidewalls of the metal gate structure 262. However, such elements are omitted for brevity. In some embodiments, the planar FET device in the region 208 is an MV device.

Still referring to FIG. 3, in some embodiments, the metal gate structure 222 of the FinFET device in the region 204, the metal gate structure 242 of the HV device in the region 206, and the metal gate structure 262 of the MV device in the region 208 include same materials. In some embodiments, the metal gate structures 222, 242 and 262 may be formed by same RPG processes. In some embodiments, each of the metal gate structures 222, 242 and 262 may include a high-k dielectric layer, a work function metal layer over the high-k dielectric layer, and a gap-filling metal layer (also referred to as a low-resistance metal layer), though not shown. In some embodiments, an interfacial layer (IL) may be formed between the high-k dielectric layer and the work function metal layer.

The IL may include an oxide-containing material such as SiO or SiON. In some embodiments, the IL covers portions of the fin structure 220. In some embodiments, the high-k dielectric layer includes a high-k dielectric material having a high dielectric constant, for example, a dielectric constants greater than that of thermal silicon oxide (˜3.9). The high-k dielectric material may include hafnium oxide (HfO₂), zirconium oxide (ZrO₂), lanthanum oxide (La₂O₃), aluminum oxide (Al₂O₃), titanium oxide (TiO₂), yttrium oxide (Y₂O₃), strontium titanate (SrTiO₃), hafnium oxynitride (HfOxNy), other suitable metal-oxides, or a combination thereof. The work function metal layer may include n-type or p-type work function metal materials, depending on the product design. Further, the work function metal layer may be a single-layered structure or multilayers of two or more materials, but the disclosure is not limited thereto. In some embodiments, the gap-filling metal layer can include conductive material such as Al, Cu, AlCu or W, but is not limited to such materials.

In some embodiments, a height of the metal gate structure 222 is defined as a vertical distance measured from a bottom surface of the metal gate structure 222 over a top of the fin structure 220 to a top surface of the metal gate structure 222. In some embodiments, a height of the metal gate structure 242 is defined as a vertical distance measured from a bottom surface to a top surface of the metal gate structure 242. In some embodiments, a height of the metal gate structure 262 is defined as a vertical distance measured from a bottom surface to a top surface of the metal gate structure 262. In some embodiments, the height of the metal gate structure 222, the height of the metal gate structure 242 and the height of the metal gate structure 262 are equal. In some embodiments, the top surface of the metal gate structure 222 is aligned (i.e., coplanar) with the top surface of the metal gate structure 242. In some embodiments, the top surface of the metal gate structure 262 is higher than the top surface of the metal gate structure 222, and higher than the top surface of the metal gate structure 242. In such embodiments, a top surface of the gate dielectric layer 250 in the region 208 is higher than the top surface of the substrate 202, and a bottom surface of the gate dielectric layer 250 is aligned (i.e., coplanar) with the top surface of the isolation structure 230. Further, the top surface of the gate dielectric layer 250 and the bottom surface of the metal gate structure 262 are both higher than the bottom surface of the metal gate structure 242, and higher than the bottom surface of the metal gate structure 222 over the top of the fin structure 220, as shown in FIG. 3.

In some embodiments, the semiconductor structure 20 further includes a first dielectric structure 270 disposed over the substrate 202. Further, the first dielectric structure 270 covers the non-planar device and all of the planar devices. In some embodiments, the first dielectric structure 270 may include a contact etch stop layer (CESL). In some embodiments, the CESL can include silicon nitride, silicon oxynitride, and/or other applicable materials. The dielectric structure 270 may include an inter-layer dielectric (ILD) structure formed on the CESL in accordance with some embodiments. The ILD structure may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon-doped silicon oxide, amorphous fluorinated carbon, parylene, bis-benzocyclobutenes (BCB), and polyimide.

In some embodiments, the semiconductor structure 20 further includes a second dielectric structure 272 disposed over the first dielectric structure 270. The second dielectric structure 272 may include a multilayered structure. For example, the second dielectric structure 272 may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon-doped silicon oxide, amorphous fluorinated carbon, parylene, bis-benzocyclobutenes (BCB), and polyimide.

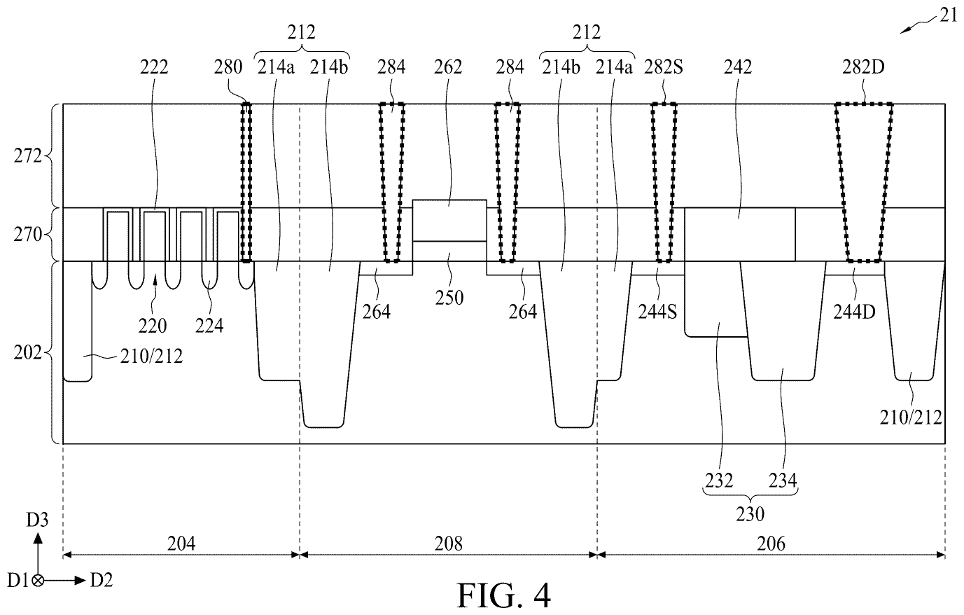

Referring to FIG. 6, in some embodiments, in operation 32, a contact structure is formed to couple to the source/drain structure 224 of the non-planar transistor device, a source contact structure is formed to couple to the source region 244S of the planar transistor device and a drain contact structure is formed to couple to the drain region 244D of the planar transistor device. Please refer to FIG. 4, which is a schematic drawings illustrating an intermediate semiconductor structure 21 including the abovementioned contact structures. In some embodiments, the semiconductor structure 21 includes a plurality of contact structures 280, 282, and 284. The contact structure 280 penetrates the first and second dielectric structures 270 and 272, and is coupled to the source/drain structure 224 of the FinFET device in the region 204. In some embodiments, a silicide structure may be disposed between the contact structure 280 and the source/drain structure 224, though not shown. The contact structure 282S penetrates the first and second dielectric structures 270 and 272, and is coupled to the source region 244S of the HV device in the region 206. The contact structure 282S is therefore referred to as a source contact structure 282S. The contact structure 282D penetrates the first and second structures 270 and 272, and is coupled to the drain region 244D of the HV device in the region 206. The contact structure 282D is therefore referred to as a drain contact structure 282D. In some embodiments, silicide structures may be disposed between the source contact structure 282S and the source region 244S, and between the drain contact structure 282D and the drain region 244D, though not shown. The contact structures 284 penetrate the first and second dielectric structures 270 and 272, and are coupled to the source/drain regions 264 of the MV device in the region 208. In some embodiments, a silicide structure may be disposed between the contact structure 284 and the source/drain structure 264, though not shown.

In some embodiments, the contact structures 280, 282S, 282D and 284 may be formed by MEOL manufacturing operations. In some embodiments, the contact structures 280, 282S, 282D and 284 may be formed simultaneously. In some embodiments, each of the contact structures 280, 282S, 282D and 284 has a slot configuration or a strip configuration. In such embodiments, the strip-type contact structures 280, 282S, 282D and 284 may extend in the direction D1, but the disclosure is not limited thereto. A width of the drain contact structure 282D is equal to and greater than a width of the source contact structure 282S. In some embodiments, the width of the drain contact structure 282D is also greater than a width of the contact structure 280, and greater than a width of the contact structure 284. In some embodiments, the width of the source contact structure 282S may be greater than the width of the contact structure 280, and the width of the contact structure 284 may be greater than the width of the contact structure 280.

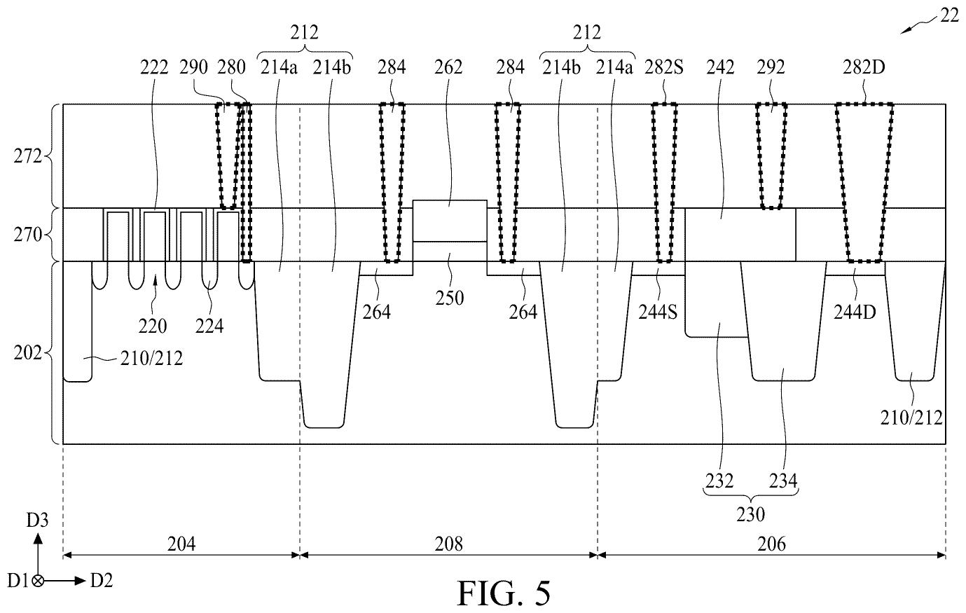

Referring to FIG. 6, in some embodiments, in operation 33, a contact structure is formed to couple to the metal gate structure 222 of the non-planar transistor device, and a gate contact structure is formed to couple to the metal gate structure 242 of the planar transistor device. Please refer to FIG. 5, which is a schematic drawing illustrating a semiconductor structure 22 including the abovementioned contact structures. In some embodiments, the semiconductor structure 22 includes the contact structures 290 and 292. The contact structure 290 penetrates the second dielectric structure 272 and is coupled to the metal gate structure 222. The contact structure 292 penetrates the second dielectric structure 272 and is coupled to the metal gate structure 242. In some embodiments, the contact structures 290 and 292 are referred to as gate contact structures. In some embodiments, the contact structure 292 extends in the direction D2. In some embodiments, the contact structures 290 and 292 both extend in the direction D2. In some embodiments, the contact structures 290 and 292 may be formed using MEOL manufacturing operations. However, the contact structures 290 and 292 may be formed prior to or after the forming of the contact structures 280, 282S, 282D and 284. Further, a width of the contact structure 292 is less than the width of the drain contact structure 282D, but greater than the width of the source contact structure 282S. In some embodiments, the width of the contact structure 292 is greater than a width of the contact structure 290. In some embodiments, the width of the contact structure 292 is greater than the width of the contact structure 284. In some embodiments, the width of the contact structure 292 is greater than the width of the contact structure 280.

Accordingly, embodiments of a semiconductor structure are provided. The semiconductor structure is formed in an HKMG process in accordance with the embodiments. The semiconductor structure includes a non-planar device and a planar device. For example but not limited thereto, a planar device for an HV application may be integrated with a non-planar device such as a FinFET device for an LV application. In some embodiments, the semiconductor structure includes contact structures for both HV devices and LV devices. The contact structures for the HV devices are have a slot configuration or a strip configuration, which is sustainable to the HV application. Further, the strip-type contact structure may replace a group of small island contact structures used in comparative embodiments. Accordingly, the strip-type contact structure is able to help reduce an area required for accommodating a source/drain region of the HV devices. Further, a process window for forming the contact structures is improved due to the relatively larger strip-type contact structures.

Some embodiments of the present disclosure provide a semiconductor structure. The semiconductor structure includes a gate structure, an isolation structure, a source region, a drain region, a source contact structure, and a drain contact structure. The gate structure is disposed over a substrate and extends in a first direction. The isolation structure is disposed between the gate structure and the substrate. The source region and the drain region are disposed at two sides of the isolation structure, and extend in the first direction. The source contact structure is coupled to the source region, and the drain contact structure is coupled to the drain region. Each of the source contact structure and the drain contact structure has a strip configuration and extends in the first direction.

Some embodiments of the present disclosure provide a method for forming a semiconductor structure. The method includes following operations. A non-planar transistor device and a planar transistor device over a substrate. A first contact structure is formed to couple to a source/drain structure of the non-planar transistor device. A source contact structure is formed to couple to a source region of the planar transistor device, and a drain contact structure is formed to couple to drain region of the planar transistor device. A second contact structure is formed to couple to a gate structure of the non-planar transistor device. A gate contact structure is formed to couple to a gate structure of the planar transistor device.

Some embodiments of the present disclosure provide a method for forming a semiconductor structure. The method includes following operations. A planar transistor device is formed over a substrate. The planar transistor device includes a gate structure, a source region and a drain region. A source contact structure is formed to couple to the source region, and a drain contact structure is formed to couple to the drain region. A gate contact structure is formed to couple to the gate structure. The gate structure, the source contact structure and the drain contact structure extend in a first direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a gate structure disposed over a substrate and extending in a first direction;
an isolation structure disposed between the gate structure and the substrate;
a source region and a drain region disposed at two sides of the isolation structure, and extending in the first direction;
a source contact structure coupled to the source region; and
a drain contact structure coupled to the drain region,
wherein each of the source contact structure and the drain contact structure has a strip configuration and extends in the first direction.

2. The semiconductor structure of claim 1, wherein a length of the source contact structure is equal to a length of the drain contact structure.

3. The semiconductor structure of claim 1, wherein a width of the source contact structure is less than a width of the drain contact structure.

4. The semiconductor structure of claim 1, further comprising a gate contact structure coupled to the gate structure.

5. The semiconductor structure of claim 4, wherein the gate contact structure comprises a strip configuration and extends in a second direction different from the first direction.

6. The semiconductor structure of claim 1, wherein the isolation structure has a first portion and a second portion coupled to the first portion, and a thickness of the first portion is less than a thickness of the second portion.

7. The semiconductor structure of claim 1, further comprising
a first silicide structure between the source region and the source contact structure; and
a second silicide structure between the drain region and the drain contact structure.

8. The semiconductor structure of claim 7, wherein a width of the second silicide structure is greater than a width of the first silicide structure.

9. The semiconductor structure of claim 1, further comprising a guard ring surrounding the gate structure, the source region and the drain region.

10. A method for forming a semiconductor structure comprising:
forming an non-planar transistor device and a planar transistor device over a substrate;
forming a first contact structure coupled to a source/drain structure of the non-planar transistor device;
forming a source contact structure coupled to a source region of the planar transistor device and a drain contact structure coupled to a drain region of the planar transistor device;
forming a second contact structure coupled to a gate structure of the non-planar transistor device; and
forming a gate contact structure coupled to a gate structure of the planar transistor device.

11. The method of claim 10, wherein the gate structure, the source region and the drain region of the planar transistor device extend in a first direction.

12. The method of claim 11, wherein the source contact structure, the drain contact structure and the first contact structure extend in the first direction.

13. The method of claim 11, wherein the non-planar transistor comprises at least a fin structure extending in a second direction different from the first direction.

14. The method of claim 13, wherein the second contact structure and the gate contact structure extend in the second direction.

15. The method of claim 10, wherein the substrate comprises at least an isolation structure separating the non-planar transistor device and the planar transistor device from each other.

16. The method of claim 10, wherein the first contact structure, the source contact structure and the drain contact structure are simultaneously formed.

17. A method for forming a semiconductor structure, comprising:
forming a planar transistor device over a substrate, wherein the planar transistor device comprises a gate structure, a source region and a drain region;
forming a source contact structure coupled to the source region and a drain contact structure coupled to the drain region; and
forming a gate contact structure coupled to the gate structure,
wherein the gate structure, the source contact structure and the drain contact structure extend in a first direction.

18. The method of claim 17, wherein the gate contact structure extends in a second direction different from the first direction.

19. The method of claim 17, wherein a length of the source contact structure is equal to a length of the drain contact structure.

20. The method of claim 17, wherein a width of the source contact structure is less than a width of the drain contact structure.
